(19) United States
(12) Patent Application Publication
(10) Pub. No.: US 2009/0155727 A1
(43) Pub. Date: Jun. 18, 2009

(54) METHOD OF FORMING A FLAT MEDIA TABLE FOR PROBE STORAGE DEVICE

(75) Inventors: Ute Drechsler, Rueschlikon (CH); Mark A. Lantz, Adliswil (CH); Hugo E. Rothuizen, Adliswil (CH)

Correspondence Address: Cantor Colburn LLP-IBM Europe, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/955,538

(22) Filed: Dec. 13, 2007

(51) Int. Cl. G03F 7/00

(52) U.S. Cl. 430/320

(57) ABSTRACT

A method of forming a flat media table for a probe-based storage device includes applying a first-photo-resistive coating to one side of a silicon wafer and a second photo-resistive coating to an opposite side of the silicon wafer. The silicon wafer includes a table layer, a suspension layer and a spacer layer sandwiched therebetween. The first photoresistive coating is applied to the table layer and the second photoresistive coating is applied to the suspension layer. A first pattern is formed through photolithography in the second photoresistive coating and etched into the suspension layer. A second pattern is formed through photolithography in the first photoresistive coating and etched into the table layer. A portion of the table layer is released from the suspension layer though selective etching of the spacer layer so as to form a plurality of stand-offs defined by remaining portions of the spacer layer.

### BACKGROUND OF THE INVENTION

1. Field of the Invention

This invention relates to the art of silicon wafer processing and, more particularly, to a method of forming a flat media table for a probe storage device.

2. Description of Background

Parallel probe-based data-storage systems are currently being developed for future data-storage applications. A parallel probe-based system employs a large array of atomic-force microscopic probes that read, write and erase data on a storage medium carried by an X/Y scanning system. The large array of probes provides the capability to achieve very high storage densities. Moreover, arranging the array of probes in parallel, high data transfer rates are also achievable. The high storage capacity combined with rapid transfer rates, allows the storage system to be built in a small package that is ideal for mobile, i.e., portable storage applications.

Mobile storage applications present a variety of engineering challenges. First, mobile storage systems must be robust against vibration and shock. Second, mobile storage systems must be capable of operating on a restricted power budget. A mobile probe based storage system should be capable of maintaining sub-nanometer tracking performance even when subjected to mechanical shocks that create accelerations that approach 10's of g's. Making a mechanical device more robust, i.e., capable of withstanding these high accelerations typically requires that the components be stiffer. However, making components stiffer results in increased power consumption for certain components, e.g., actuators. Any increase in power consumption makes the device less desirable for mobile applications. In addition, the speed and precision of the probe-based system spawns numerous system requirements. In order to maintain sub-nanometer tracking, storage media table must be flat and shock resistant. Designing and fabricating components that meet the requirements for precision positioning, e.g., vibration rejection, shock robustness, low power consumption, fast seek performance, flat media, and low cost is a constant challenge.

### SUMMARY OF THE INVENTION

The shortcomings of the prior art are overcome and additional advantages are provided through the provision of a method of forming a flat media table for a probe-based storage device. The method includes applying a first a photoresistive coating to one side of a silicon wafer and a second photo-resistive coating to an opposite side of the silicon wafer. The silicon wafer includes a table layer, a suspension layer and a spacer layer sandwiched between the table layer and the suspension layer. The first photoresistive coating is applied to the table layer and the second photoresistive coating is applied to the suspension layer. A first pattern is formed through photolithography in the second photoresistive coating and etched into the suspension layer. A second pattern is formed through photolithography in the first photoresistive coating and etched into the table layer. A portion of the table layer is released from the suspension layer though selective etching of the spacer layer so as to form a plurality of stand-offs defined by remaining portions of the spacer layer.

Additional features and advantages are realized through the techniques of exemplary embodiments of the present invention. Other embodiments and aspects of the invention are described in detail herein and are considered a part of the claimed invention. For a better understanding of the invention with advantages and features, refer to the description and to the drawings.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 illustrates a silicon wafer including a table layer, a suspension layer and a spacer layer;

FIG. 2 illustrates the silicon wafer of FIG. 1 after application of first and second photoresistive coatings and an optional media layer;

FIG. 3 illustrates the silicon wafer of FIG. 2 after a pattern is etched in-to the suspension layer to form the suspension system;

FIG. 4 illustrates the silicon wafer of FIG. 3 after a pattern is etched into the table layer;

FIG. 5 illustrates the silicon wafer of FIG. 4 after the table layer is selectively released from the suspension layer; and

FIG. 6 illustrates the silicon wafer of FIG. 5 after the first and second photoresistive coatings are removed.

The detailed description explains the exemplary embodiments of the invention, together with advantages and features, by way of example with reference to the drawings.

### DETAILED DESCRIPTION OF THE INVENTION

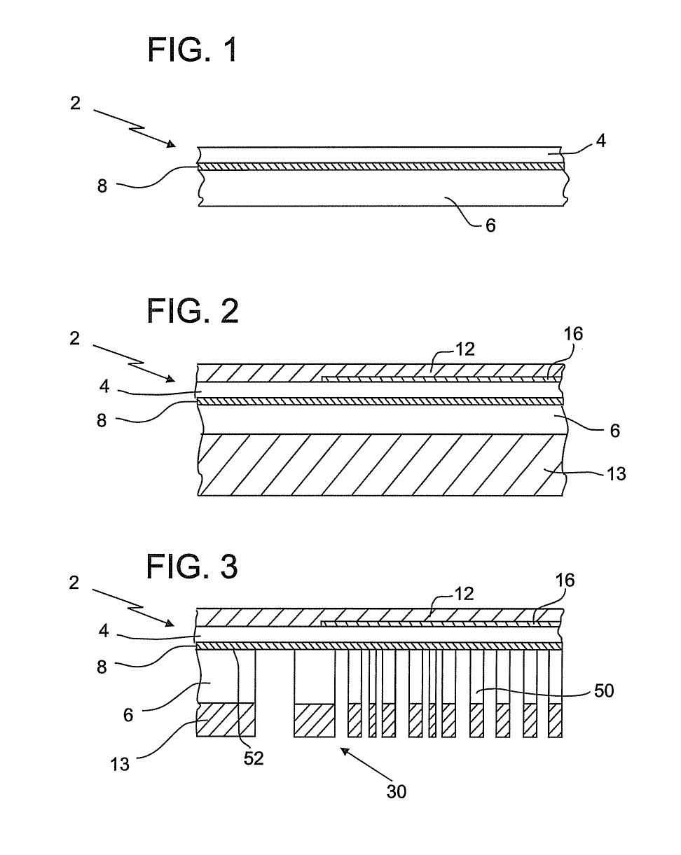

Turning now to the drawings in greater detail, it will be seen that in FIG. 1, there is shown a silicon wafer generally indicated at 2. In accordance with the exemplary embodiment shown, silicon wafer 2 is a commercially available silicon-on-insulator (SOI) material including a table layer 4 having an exemplary thickness of about 10-50 μm silicon, a suspension layer 6 having an exemplary thickness of about 200-600 μm silicon and a spacer layer 8 having an exemplary thickness of about 0.4-3 μm. In accordance with an exemplary embodiment of the invention, spacer layer 8 is formed from silicon dioxide, which is selectively etchable relative to table layer 4 and suspension layer 6. Of course, it should be understood that the particular arrangement of the various layers in silicon wafer 2 is exemplary and can be altered depending upon various user requirements. In accordance with the exemplary embodiment shown, silicon wafer 2 is employed in connection with a parallel probe-based data-storage system and thus requires a flat media table.

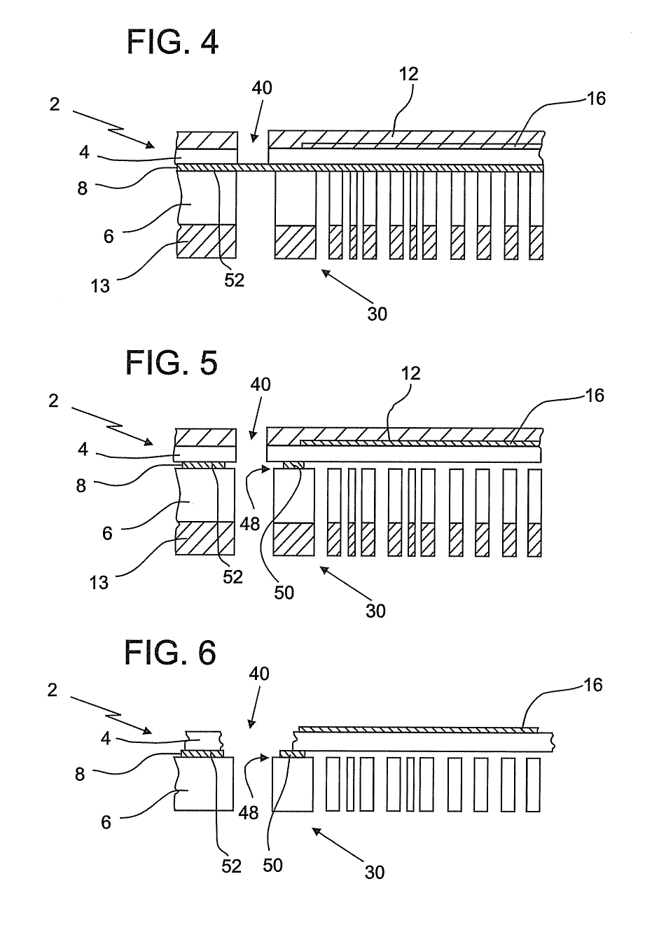

As best shown in FIGS. 2 through 4, a media table (not separately labeled) is formed by initially applying a first photoresistive coating or layer 12 to table layer 4 on one side of wafer 2 and a second photoresistive coating or layer 13 to suspension layer 6 on the opposite side of wafer 2. In addition to photoresistive layer 12, a media layer 16 of, e.g. polymer, phase-change, or ferroelectric material is optionally applied to table layer 4. Of course, it should be understood that the media layer is an optional component that can be omitted or substituted with another component depending particular end requirements. In any event, after applying first and second photoresistive layers 12 and 13 onto table layer 4 and suspension layer 6 respectively, a first pattern 30 is formed within second photoresistive layer 13 and a second pattern 40 is formed within first photoresistive layer 12. At this point, first pattern 30 is etched through suspension layer 6, stopping on spacer layer 8 (FIG. 4) to form a suspension system (not separately labeled). Similarly, second pattern 40 is etched through table layer 4. In a manner, similar to that described above, etching is stopped on spacer layer 8, but on the opposite side thereof with respect to the etching of first pattern 30.

As shown in FIG. 5, after first and second patterns 30 and 40 are defined, table layer 4 is partially released from suspension layer 6 by selectively etching spacer layer 8. More specifically, a hydrofluoric acid (HF) vapor process is employed to form lateral gaps through lateral underetching, such as indicated at 48, between table layer 4 and suspension layer 6, thereby leaving behind a plurality of small portions or anchor points, one of which is shown at 50. In addition to anchor points 50, an outer frame 52 is left behind following the final etching process. Anchor points 50 combine with a suspension system (not separately labeled) etched into suspension layer 6 to minimize displacements that result from a mechanical shock to table layer 4. That is, anchor points 50 and outer frame 52 serve as stand-offs that fixedly interconnect suspension layer 6 and table layer 4. Minimizing the size and the number of anchor points 50 minimizes warping of table layer 4. At this point, it should be appreciated that the present invention provides a flat media table that is isolated from vibration effects created by mechanical shocks, thereby forming a silicon positioning system designed for probe storage applications that can be maintained within a small package. Moreover, the present invention establishes a flat table layer that is robust and designed to be employed in connection with low-power components. In this manner, the flat media table is tailored for mobile storage applications. Of course, the flat media table can also be used in a variety of other applications.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

1. A method of forming a flat media table for a probe-based storage device, the method comprising:
applying a first a photoresistive coating to one side of a silicon wafer and a second photoresistive coating to an opposite side of the silicon wafer, the silicon wafer including a table layer, a suspension layer and a spacer layer sandwiched between the table layer and the suspension layer, wherein the first photoresistive coating is applied to the table layer and the second photoresistive coating is applied to the suspension layer;
forming a first pattern through photolithography in the second photoresistive coating;
forming a second pattern through photolithography in the first photoresistive coating;
etching the first pattern into the suspension layer;
etching the second pattern into the table layer; and
releasing a portion of the table layer from the suspension layer though selective etching of the spacer layer so as to form a plurality of stand-offs defined by remaining portions of the spacer layer.

2. The method of claim 1, wherein the plurality of stand-offs fixedly connect the table layer and the suspension layer.

3. The method of claim 1, wherein, the selective etching of the spacer layer comprises lateral underetching of the spacer layer with respect to the table layer and suspension layer.

4. The method of claim 3, wherein the selective etching of the spacer layer comprises employing a vapor of hydrofluoric acid (HF) to selectively dissolve portions of the spacer layer.
